(19) United States
(12) Patent Application Publication
(10) Pub. No.: US 2021/0108316 A1
(43) Pub. Date: Apr. 15, 2021

(54) PLATING METHOD, PLATING SYSTEM, AND RECORDING MEDIUM

(71) Applicant: Tokyo Electron Limited, Tokyo (JP)

(72) Inventors: Nobutaka Mizutani, Tokyo (JP); Kazutoshi Iwai, Kikuchi-gun, Kumamoto (JP)

(21) Appl. No.: 16/498,503

(22) PCT Filed: Mar. 22, 2018
(86) PCT No.: PCT/JP2018/011364

§ 371 Date: Sep. 27, 2019

(30) Foreign Application Priority Data
Mar. 31, 2017 (JP) 2017-072410

(51) Int. Cl. C23C 18/18; C23C 18/16

(52) U.S. Cl. CPC C23C 18/1893; C23C 18/1675; C23C 18/165; C23C 18/1619

(57) ABSTRACT

A substrate processing method includes preparing a substrate having, on a surface thereof, a first portion made of a silicon compound including nitrogen and a second portion made of a material different from the first portion; forming a SAM (Self-Assembled Monolayer) on the surface of the substrate; imparting a catalyst to the substrate by supplying a catalyst containing liquid onto the substrate on which the SAM is formed; and performing a plating on the substrate to which the catalyst is imparted. The forming of the SAM is carried out by supplying a SAM forming chemical, which does not have a functional group including nitrogen, onto the substrate.

### TECHNICAL FIELD

The various aspects and embodiments described herein pertain generally to a technique of performing a selective plating on a surface of a substrate such as a semiconductor wafer.

### BACKGROUND

Various materials such as a metal, silicon nitride (simply referred to as “SiN” in the present exemplary embodiment), and silicon oxide (simply referred to as “SiO” in the present exemplary embodiment) are exposed on a surface of a substrate such as a semiconductor wafer in the course of manufacturing a semiconductor device. From the viewpoint of improving productivity of the semiconductor device, a selective plating technique of forming a plating film only on a part of these various materials by electroless plating is recently attracting attention. The selective plating technique is expected to bring about various effects such as reduction of the number of manufacturing processes required, improvement of processing accuracy for a pattern shape, and so forth.

When carrying out the electroless plating, in order to efficiently adhere a catalyst such as palladium (Pd) serving as a nucleus of precipitation of the plating film to the surface of the substrate, a self-assembled monolayer (SAM) is frequently formed on the surface of the substrate by applying a coupling agent such as a silane coupling agent onto the surface of the substrate. In the field of the manufacture of the semiconductor device, one having an amino group (—NH₂) as a functional group may be used as an example of the silane coupling agent (see, for example, Patent Document 1). The self-assembled monolayer which has the amino group (—NH₂) at a side opposite from the surface of the substrate easily adsorbs the Pd catalyst.

Further, it may be required to perform the selective plating to form the plating film only on a portion other than SiN, for example, only on a surface of a portion made of a conductive material, without forming the plating film on a surface of the SiN. The SiN, however, easily adsorbs the Pd catalyst due to N atoms included therein. Further, even if the surface of the SiN is covered with the silane coupling agent having the amino group (—NH₂) at an end thereof (which has been generally used in the art) before the Pd catalyst is applied, the Pd catalyst strongly adheres to a surface of a layer made of this silane coupling agent. Accordingly, it is very difficult to suppress the plating film from being formed on the surface of the SiN.

### PRIOR ART DOCUMENT

Patent Document 1: Japanese Patent Laid-open Publication No. 2012-216732

### DISCLOSURE OF THE INVENTION

In view of foregoing, exemplary embodiments provide a plating method capable of allowing a plating film not to be formed at least on a first portion of a substrate which has the first portion made of a silicon compound including nitrogen and a second portion made of a material different from the first portion.

In one exemplary embodiment, a plating method comprises preparing a substrate having, on a surface thereof, a first portion made of a silicon compound including nitrogen and a second portion made of a material different from the first portion; forming a SAM (Self-Assembled Monolayer) on the surface of the substrate; imparting a catalyst to the substrate by supplying a catalyst containing liquid onto the substrate on which the SAM is formed; and performing a plating on the substrate to which the catalyst is imparted. The forming of the SAM is carried out by supplying a SAM forming chemical, which does not have a functional group including nitrogen, onto the substrate.

According to the exemplary embodiment, the SAM which does not have the functional group including nitrogen firmly adheres to a surface of the first portion made of the silicon compound including the nitrogen, and this SAM hinders a catalyst adsorption ability of the nitrogen in the silicon compound. Accordingly, the catalyst never or hardly adheres to a surface of the silicon compound containing the nitrogen. Thus, the plating film does not grow at least on the first portion in a plating processing. By selecting, as a material forming the second portion, a material to which the SAM hardly adheres and which has a catalyst adsorption property, a selective plating can be carried out.

### BRIEF DESCRIPTION OF THE DRAWINGS

FIG. 1A is a schematic longitudinal cross sectional view illustrating a structure of a substrate as a plating target.

FIG. 1B is a schematic longitudinal cross sectional view illustrating a state of the substrate after a SAM forming processing.

FIG. 1C is a schematic longitudinal cross sectional view illustrating the state of the substrate after a catalyst applying processing and a rinsing processing.

FIG. 1D is a schematic longitudinal cross sectional views illustrating the state of the substrate after a plating processing.

FIG. 2 is a diagram schematically illustrating a configuration of an apparatus (spinner) for use in performing a plating method.

FIG. 3 is a diagram schematically illustrating a configuration of an apparatus (deposition apparatus) for use in performing the plating method.

FIG. 4 is a diagram schematically illustrating a configuration of an apparatus (bake apparatus) for use in performing the plating method.

FIG. 5 is a schematic plan view illustrating an example of a plating system including the apparatuses shown in FIG. 2 to FIG. 4 for use in performing the plating method.

### DETAILED DESCRIPTION

Hereinafter, a plating method will be explained with reference to the accompanying drawings.

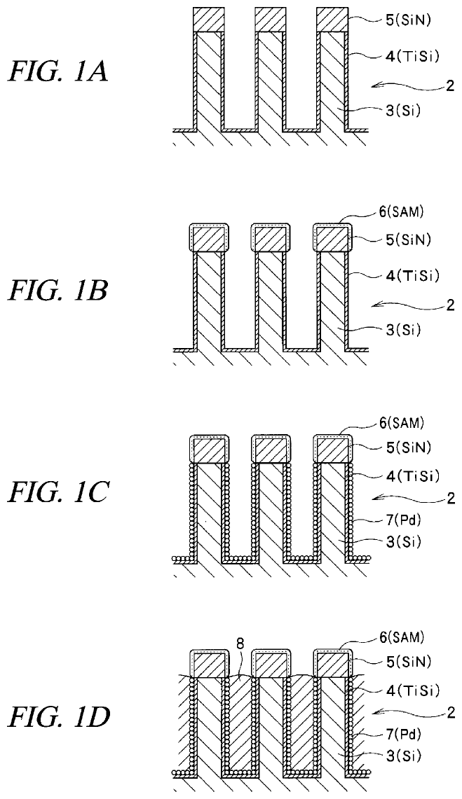

First, a structure of a substrate 1 as a plating processing target according to an exemplary embodiment will be described. As shown in FIG. 1A, the substrate 2 has a silicon (hereinafter, referred to as “Si”) layer 3 provided with trenches (recesses or grooves); a titanium silicide (hereinafter, referred to as “TiSi”) layer 4 formed on a surface forming an inner wall surface of the trench of the Si layer 3; and a silicon nitride (hereinafter, referred to as “SiN”) layer 5 formed on a top surface of a column-shaped body between the trenches of the Si layer 3. The plating method to be described below is directed to forming a plating layer 8 (see FIG. 1D) on a surface of the TiSi layer 4 without forming a plating film on a surface of the SiN layer 5. Below, the plating method will be described in detail.

[Pre-Cleaning Processing]

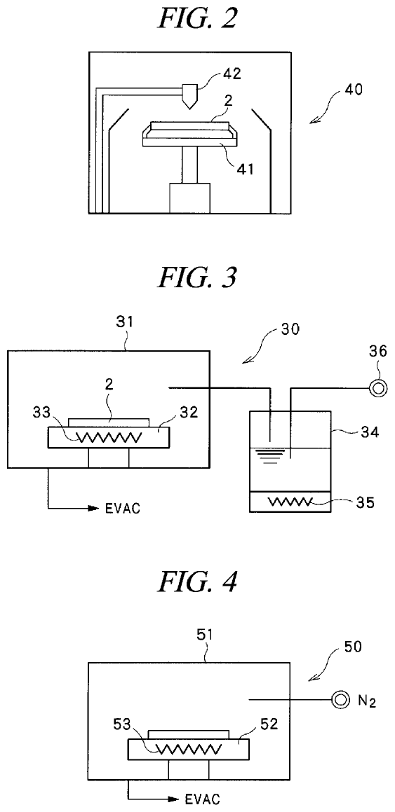

First, a SC1 cleaning processing and a rinsing processing are performed in sequence as a pre-cleaning processing to remove a particle, an organic contaminant, and so forth from the surface of the substrate. The pre-cleaning processing may be performed by a spinner (rotary liquid processing apparatus) 40. FIG. 2 schematically illustrates a configuration of the spinner 40. To elaborate, the pre-cleaning processing may be performed by holding the substrate 2 horizontally and rotating the substrate 2 around a vertical axis by a spin chuck 41, supplying a SC1 solution from a nozzle 42 toward a central portion of the surface of the substrate being rotated for a predetermined time period, and then supplying a rinse liquid, for example, DIW from the nozzle 42 for a preset time period, as depicted in FIG. 2.

[SAM Forming Processing]

Subsequently, a SAM forming processing is performed to form, on the surface of the substrate 2, a silane-based self-assembled monolayer (SAM) layer 6 (hereinafter, referred to as “SAM layer”) which does not have a functional group including N. In the formation of the SAM layer 6, a chemical for SAM layer formation (SAM forming chemical) is supplied onto the surface of the substrate 2. A chemical called a silane coupling agent or a chemical having a similar molecular structure thereto may be used as the chemical for SAM layer formation. Here, a product named “KBE-3033,” which is an alkoxysilane-based chemical and can be commercially purchased from Shin-Etsu Chemical Co., Ltd., may be used as the chemical for SAM layer formation. A chemical name of KBE-3033 is n-propylpropyltriethoxysilane, and a structural formula thereof is (C₂H₅O)₃Si(CH₂)₂CH₃. This chemical does not have a functional group including N but has a functional group represented by a general expression C_{X}H_{Y} (specifically, (CH₂)₂—CH₃) at an opposite side from three O-ethoxy groups (which involve in the bond to the surface of the substrate 2).

The SAM layer 6 may be formed by a liquid processing or a deposition processing.

When forming the SAM layer 6 by the liquid processing, the spinner 40 having the configuration schematically illustrated in FIG. 2 and serving as a SAM forming device may be used. In this case, the substrate 2 is horizontally held and rotated around the vertical axis by the spin chuck 41 of the spinner 40 shown in FIG. 2. By supplying the chemical for SAM layer formation from the nozzle 42 toward the central portion of the surface of the substrate 2 being rotated, a thin film of the chemical is formed on the surface of the substrate 2. Thereafter, a baking processing is performed on the thin film of the chemical. This baking processing may be carried out by heating the substrate in a low-oxygen atmosphere, for example, in a nitrogen gas atmosphere. To elaborate, a heating apparatus (bake apparatus) 50 having a configuration schematically illustrated in FIG. 4 may be used. The substrate 2 is placed on a placing table (hot plate) 52 provided within a processing chamber 51 in which a nitrogen gas atmosphere is set, and the substrate 2 is heated to, e.g., 100° C. by a heater 53 provided within the placing table 52. Through this baking (bake) processing, the SAM layer 6 is formed.

When forming the SAM layer 6 by the deposition processing, a vacuum deposition apparatus 30 having a configuration schematically illustrated in FIG. 3 may be used. In this case, the substrate 2 is placed on a placing table 32 provided within a processing chamber 31 in which a low-oxygen atmosphere (for example, a nitrogen gas atmosphere or a decompressed atmosphere) is set, and the substrate 2 is heated to, e.g., 100° C. by a heater 33 provided within the placing table 32. In this state, the chemical for SAM layer formation stored in a tank 34 in a liquid state is heated to be vaporized by the heater 35. The vaporized chemical is supplied into the processing chamber 31 by being carried with a carrier gas (for example, a nitrogen gas) which is supplied from a carrier gas source 36. In case of using the deposition processing, the baking processing need not be performed.

[Catalyst Imparting Processing]

Subsequently, by supplying a Pd nano colloid solution, that is, a catalyst particle solution onto the substrate 2, a catalyst imparting processing is performed. The Pd nano colloid solution is prepared by dispersing Pd nanoparticles (Pd-NPs) as metal catalyst particles and polyvinylpyrrolidone (PVP) as a dispersant covering the Pd nanoparticles in a solvent.

The catalyst imparting processing may be performed by using the spinner 40 having the configuration schematically illustrated in FIG. 2 and serving as a catalyst imparting device. At this time, the substrate 2 is horizontally held and rotated around the vertical axis by the spin chuck 41 of the spinner 40, and a catalyst containing liquid is discharged from the nozzle toward the central portion of the surface of the substrate 2 being rotated. Desirably, the catalyst containing liquid is adjusted to be acid.

Upon the completion of the catalyst imparting processing, a catalyst particle-containing layer 7 adheres to a surface of the TiSi layer 4 (the SAM layer 6 does not mostly adhere to this TiSi layer 4). Meanwhile, the catalyst hardly adheres to the SAM layer 6 on the surface of the SiN layer 5 (the reason for this will be explained later). Further, it is desirable that the catalyst containing liquid is acid. In such a case, a difference in the degrees of adhesion of the catalyst becomes larger, so that selectivity of the plating can be improved.

[Rinsing Processing]

Subsequently, a rinsing processing is performed. This rinsing processing may be carried out by holding and rotating the substrate 2 by the spin chuck 41 after the catalyst imparting processing, while discharging pure water (DIW) as a rinse liquid from the nozzle toward the central portion of the surface of the substrate 2 being rotated. The bake processing may be performed after the rinsing processing.

[Plating Processing]

Then, a plating layer 8 made of copper (Cu), tungsten (W), cobalt (Co), nickel (Ni) or an alloy thereof is formed by electroless plating. This plating processing may be performed by using the spinner 40 having the configuration schematically illustrated in FIG. 2 and serving as a plating device. At this time, the substrate 2 is horizontally held and rotated around the vertical axis by the spin chuck 41 of the spinner 40, and a plating liquid is supplied from the nozzle toward the central portion of the surface of the substrate 2 being rotated.

Through this plating processing, the plating layer 8 is selectively formed only on the surface of the TiSi layer 4 to which the catalyst particle-containing layer 7 adheres. Meanwhile, the plating layer 8 is not formed on the surface of the SAM layer 6 on the SiN layer 5 to which the catalyst particle-containing layer 7 is not attached. The plating layer 8 is formed within the trench (recess) in a bottom-up manner. That is, the plating layer 8 is formed only within the trench required to be filled, and is not formed on a portion (the surface of the SiN layer 4) where the plating layer is not required to be formed. Therefore, it is not needed to remove an extra plating layer after the plating processing, or the number of processes required to be performed to remove the extra plating layer can be greatly reduced. When the recess is filled by CVD (Chemical Vapor Deposition) or ALD (Atomic Layer Deposition) where a selective growth cannot be achieved, the plating layer is formed on the entire surface of the substrate 2. As a result, a void may be formed within the recess. According to the method of the present exemplary embodiment, however, the recess can be filled without having the void therein.

When the plating processing is actually performed according to the above-described sequence, the plating layer 8 is selectively formed only on the TiSi layer 4 and is not formed on the SiN layer 5.

The reason why the selective plating is enabled by the above-stated method is not completely understood. However, the present inventors assume the following.

A SAM material (a material forming the SAM layer 6) once adheres to the TiSi layer 4 and the SiN layer 5. However, the SAM material existing on the TiSi layer 4 is removed by an end time point of the rinsing process, at the latest, for at least one of the following reasons (1) and (2), so that only the SAM material existing on the SiN layer 5 remains.

(1) A bonding force of the SAM material to the TiSi layer 4 as a metal layer is weaker than a bonding force of the SAM material to the SiN layer 5. Accordingly, when the catalyst containing liquid or the rinse liquid is supplied to the substrate 2, the SAM material on the TiSi layer 4 may be easily removed by a physical force caused by a flow of the liquid.

(2) The surface of the TiSi layer 4 as the metal layer is eroded by the catalyst containing liquid which is adjusted to be alkaline or acid. As a result, the SAM material once attached to the surface of the TiSi layer 4 is removed from the TiSi layer 4. Meanwhile, since the surface of the SiN layer 5 is not eroded by the catalyst containing liquid adjusted to be acid or alkaline, the SAM material on the SiN layer 5 still remains on the SiN layer 5 even after the catalyst containing liquid is supplied onto the substrate 2.

The SAM material which does not have a functional group including N (nitrogen) atoms hardly adsorbs the catalyst metal (here, the Pd particles). Further, the Pd particle adsorption property of the SiN layer 5 under the SAM layer 6 is not substantially exerted as the surface of the SiN layer 5 is covered with the SAM material which does not have the function group including the N (nitrogen) atoms. Therefore, even if the Pd particles are attached to the SAM layer 6, these Pd particles are removed from the SAM layer 6 by the time when the rinsing processing is completed, at the latest.

Meanwhile, the Pd particles directly adhere onto the TiSi layer 4. The present inventors assume that a mechanism of this adhesion is as follows. As a pH of the catalyst containing liquid is adjusted such that a potential of the surface of the substrate and a potential of the Pd particles have opposite polarities, the Pd particles in the catalyst containing liquid are attracted to be attached to the surface of the substrate. The attached Pd particles stay on the surface of the substrate strongly by the Van der Waals force.

The present disclosure is not limited to the above-stated principles. However, it is clear that the above-described sequence enables the selective plating.

In the above-described exemplary embodiment, the metal catalyst included in the catalyst containing liquid is the palladium (Pd). However, the metal catalyst is not limited thereto and may be, by way of still non-limiting example, gold (Au), platinum (Pt), ruthenium (Ru), or the like.

In the above-described exemplary embodiment, the dispersant included in the catalyst particle solution is polyvinylpyrrolidone (PVP). However, the exemplary embodiment is not limited thereto. By way of non-limiting example, the dispersant may be polyacrylic acid (PAA), polyethyleneimine (PEI), tetramethyl ammonium (TMA), citric acid, or the like.

As the chemical called the silane coupling agent having the functional group represented by the aforementioned expression of C_{X}H_{Y} (specifically, represented by (CH₂)₂—CH₃), or the chemical having the similar molecular structure (to elaborate, having, at a first end, an O-methoxy group or an O-ethoxy group as a group which involves in the bond to the substrate and having, at a second end, the C_{X}Y_{Y} group), besides the aforementioned n-propylpropyltriethoxysilane (KBE-3033), one of the followings may be used: vinyltrimethoxysilane (KBM-1003), vinyltriethoxysilane (KBE-1003), 2-(3,4 epoxycyclohexyl) ethyltrimethoxysilane (KBM-303), 3-glycidoxypropyl methyldimethoxysilane (KBM-402), 3-glycidoxypropyl trimethoxysilane (KBM-403), 3-glycidoxypropyl methyldiethoxysilane (KBE-402) and 3-glycidoxypropyl triethoxysilane (KBE-403). These chemicals have chemical names specified in the parentheses and can be commercially purchased from Shin-Etsu Chemical Co., Ltd.

Further, as the chemical called a silane coupling agent having an amino group which is not suitable for use in the present exemplary embodiment, or a chemical having a molecular structure similar thereto (to elaborate, having, at a first end, an O-methoxy group or an O-ethoxy group as a group which involves in the bond to the substrate and having, at a second end, the amino group), for example, one of the followings may be used: N-2-(aminoethyl)-3-aminopropylmethyldimethoxysilane (KBM-602), N-2-(aminoethyl)-3-aminopropyltrimethoxysilane (KBM-603), 3-aminoprolyltrimethoxysilane (KBM-903) and 3-aminopropyltrimethoxysilane (KBE-903). These chemicals have chemical names specified in the parentheses and can be commercially purchased from Shin-Etsu Chemical Co., Ltd.

In the above-described plating method, the layer to which the plating layer is not required to be attached may be, besides the SiN, a layer made of a film including N, such as SiCN (silicon carbonitride), SiON (silicon oxynitride), SiOCN (silicon oxycarbonitride).

Furthermore, TEOS is often exposed on the surface of the substrate. However, it is found out that the plating layer is suppressed from being formed on the TEOS by using the above-stated plating method.

In the above-described plating method, the layer to which the plating layer is required to be attached may be, besides the TiSi, a layer made of a conductive material such as Ti, Si or Si doped with B or P. A material forming the layer to which the plating layer is required to be attached is not particularly limited as long as it is difficult for the SAM not having the functional group including the nitrogen to adhere to the material and the material has the catalyst adsorption property.

The plating method is not limited to burying the plating metal in the trench structure shown in FIG. 1A. The above-described plating method may be performed to form the plating layer selectively on a flat surface of a substrate on which various materials are exposed. In such a case, the plating layer may be used as a hard mask for drying etching, for example.

The above-described series of processings, that is, the pre-cleaning processing, the SAM forming processing, the baking (bake) processing, the catalyst imparting processing, the rinsing processing and the plating processing may be performed by a plating system schematically illustrated in FIG. 4.

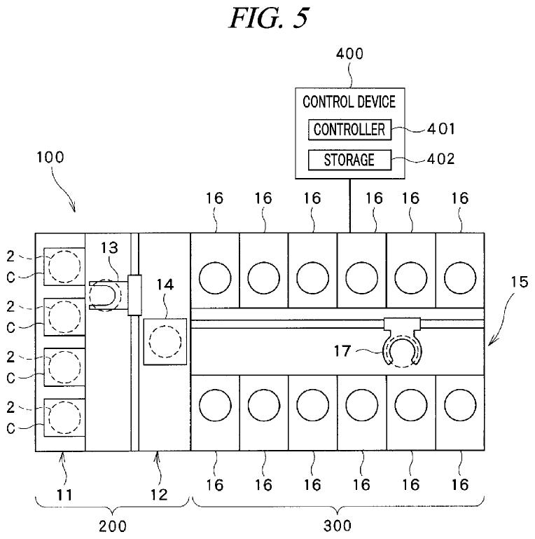

In the plating system 100 shown in FIG. 5, a substrate transfer device 13 provided in a carry-in/carry-out station 200 takes out the substrate 2 from a carrier C placed in a carrier placing section 11, and places the taken substrate 2 on a delivery unit 14. Each of processing units 16 provided in a processing station 300 is configured to perform at least any one of the aforementioned series of processings. That is, some of the processing units 16 are the apparatuses 30, 40 and 50 shown in FIG. 2A to FIG. 2C. The substrate 2 placed on the delivery unit 14 is taken out from the delivery unit 14 by a substrate transfer device 17 of the processing station 300 and carried into the processing units 16 corresponding to the above-stated processings in sequence, and a preset processing is performed in each processing unit 16. Upon the completion of the series of processings, the substrate 2 is taken out from the processing unit 16 and placed on the delivery unit 14. Then, the substrate 2 placed on the delivery unit 14, which is finished with the processings, is returned back into the carrier C by the substrate transfer device 13.

The plating system 100 is equipped with a control device 400. The control device 400 is, for example, a computer, and includes a controller 401 and a storage 402. The storage 402 stores programs which control various processings performed in the plating system 100. The controller 401 controls operations of the plating system 100 by reading out and executing the programs stored in the storage 402. That is, the control device 400 controls operations of the individual processing units 16 and transfers of the substrate 2 by the substrate transfer devices 13 and 17 to perform the above-described series of processings regarding the plating.

Further, the programs may be recorded in a computer-readable recording medium, and installed from the recording medium to the storage 402 of the control device 400. The computer-readable recording medium may be, for example, a hard disc (HD), a flexible disc (FD), a compact disc (CD), a magnet optical disc (MO), or a memory card.

### EXPLANATION OF CODES

1: Substrate
4: Second portion (TiSi layer)
5: first portion made of silicon compound including nitrogen (SiN layer)
6: Self-assembled monolayer (SAM layer)
7: catalyst (catalyst particle-containing layer)
8: Plating (plating layer)

We claim:

1. A plating method, comprising:
preparing a substrate having, on a surface thereof, a first portion made of a silicon compound including nitrogen and a second portion made of a material different from the first portion;
forming a SAM (Self-Assembled Monolayer) on the surface of the substrate;
imparting a catalyst to the substrate by supplying a catalyst containing liquid onto the substrate on which the SAM is formed; and
performing a plating on the substrate to which the catalyst is imparted,
wherein the forming of the SAM is carried out by supplying a SAM forming chemical, which does not have a functional group including nitrogen, onto the substrate.

2. The plating method of claim 1,
wherein the second portion is made of a conductive material.

3. The plating method of claim 2,
wherein the silicon compound including the nitrogen is Si, SiCN, SiON, or SiOCN, and the conductive material is TiSi, TiN, Si, or Si doped with B or P.

4. The plating method of claim 1,
wherein the catalyst containing liquid is acid.

5. The plating method of claim 1, further comprising:
supplying a rinse liquid onto the surface of the substrate after the imparting of the catalyst and before the performing of the plating.

6. The plating method of claim 1,
wherein the forming of the SAM is carried out by baking the substrate in a low-oxygen atmosphere after supplying a chemical liquid as the SAM forming chemical onto the substrate.

7. A computer-readable recording medium having stored thereon computer-executable instructions that, in response to execution, cause a plating system to perform a plating method as claimed in claim 1.

8. A plating system, comprising:
a SAM forming device configured to form a SAM (Self-Assembled Monolayer) on a surface of a substrate by supplying a SAM forming chemical, which does not have a functional group including nitrogen, onto the substrate;
a catalyst imparting device configured to impart a catalyst to the substrate by supplying a catalyst solution onto the substrate on which the SAM is formed; and
a plating device configured to perform a plating on the substrate to which the catalyst is imparted.
